(19) United States
(12) Patent Application Publication
(10) Pub. No.: US 2025/0132234 A1
(43) Pub. Date: Apr. 24, 2025

(54) INTERPOSER AND SEMICONDUCTOR PACKAGE INCLUDING THE SAME

(71) Applicant: SAMSUNG ELECTRONICS CO., LTD, Suwon-si (KR)

(72) Inventors: Yongjae KIM, Suwon-si (KR); Hyeonjae KIM, Suwon-si (KR); Sungwoo PARK, Suwon-si (KR); Junseop BYEON, Suwon-si (KR); Semin OH, Suwon-si (KR)

(73) Assignee: SAMSUNG ELECTRONICS CO., LTD., Suwon-si (KR)

(21) Appl. No.: 18/652,312

(22) Filed: May 1, 2024

(30) Foreign Application Priority Data
Oct. 19, 2023 (KR) 10-2023-0140724

(51) Int. Cl. H01L 23/498; H01L 23/522; H01L 23/528

(52) U.S. Cl. CPC H01L 23/49811; H01L 23/5226; H01L 23/5283

(57) ABSTRACT

Disclosed are interposers and semiconductor packages. The interposer includes a core layer, an upper wiring layer on the core layer, a plurality of lower pads on a bottom surface of the core layer, a plurality of through vias that vertically penetrate the core layer and electrically connect the upper wiring layer to the lower pads, and a dummy structure on a lower portion of the core layer. The dummy structure includes a dummy layer whose bottom surface is coplanar with the bottom surface of the core layer, a barrier layer between the core layer and the dummy layer, and a dielectric layer between the core layer and the barrier layer. The dummy structure is horizontally spaced apart and electrically insulated from the through vias.

### CROSS-REFERENCE TO RELATED APPLICATION

This U.S. nonprovisional application is based on and claims priority to Korean Patent Application No. 10-2023-0140724 filed on Oct. 19, 2023, in the Korean Intellectual Property Office, the disclosure of which is hereby incorporated by reference in its entirety.

### BACKGROUND

### 1. Field

The disclosure relates to a semiconductor package, and more particularly, to a semiconductor package including an interposer.

### 2. Description of Related Art

In accordance with rapid development of the needs of the electronic industry and users, electronic devices tend to have compact size, multi-functionality, and high capacity, and thus it is beneficial to have a semiconductor package including a plurality of semiconductor chips.

An increase in integration of the plurality of semiconductor chips included in the semiconductor package can cause printed circuit boards to fail. Therefore, a semiconductor package including an interposer to connect the plurality of semiconductor chips to each other is needed.

### SUMMARY

Provided is a semiconductor package including an interposer with improved structural stability.

According to an aspect of the disclosure, an interposer includes: a core layer; an upper wiring layer on the core layer; a lower pad on a bottom surface of the core layer; a through via that vertically penetrates the core layer and connects the upper wiring layer to the lower pad; and a dummy structure on a lower portion of the core layer, wherein the dummy structure includes: a dummy layer including a bottom surface that is coplanar with the bottom surface of the core layer; a barrier layer between the core layer and the dummy layer; and a dielectric layer between the core layer and the barrier layer, and wherein the dummy structure is horizontally spaced apart from the through via and is electrically insulated from the through via.

According to an aspect of the disclosure, a semiconductor package includes: a package substrate; an interposer on the package substrate; a semiconductor chip on the interposer; and a chip stack on the interposer and horizontally spaced apart from the semiconductor chip, wherein the interposer includes: a core layer; an upper wiring layer on the core layer; a dummy structure in the core layer and exposed on a bottom surface of the core layer; a passivation layer that covers the dummy structure and the bottom surface of the core layer; a through via that vertically penetrates the core layer and the passivation layer and is connected to the upper wiring layer; and a lower pad on the bottom surface of the core layer, wherein the lower pad is connected to the through via, wherein the dummy structure is vertically spaced apart from the upper wiring layer, and wherein the dummy structure is electrically insulated from the upper wiring layer.

According to an aspect of the disclosure, an interposer includes: a core layer; an upper wiring layer on a top surface of the core layer, the upper wiring layer including an upper dielectric pattern and an upper wiring pattern in the upper dielectric pattern; a dummy structure on a lower portion of the core layer, the dummy structure including a bar shape; a first passivation layer that covers the dummy structure and a bottom surface of the core layer; a through via that vertically penetrates the core layer and connects to the upper wiring layer, wherein a bottom surface of the through via is coplanar with a bottom surface of the first passivation layer; a lower pad on the bottom surface of the first passivation layer and connected to the through via; a second passivation layer that covers the bottom surface of the first passivation layer and includes a recess exposing a portion of a bottom surface of the lower pad; and an under-bump pattern on the recess, wherein the dummy structure includes: a dummy layer including a bottom surface that is coplanar with the bottom surface of the core layer; a conductive layer that covers a top surface of the dummy layer and a lateral surface of the dummy layer, wherein a lowermost surface of the conductive layer is coplanar with the bottom surface of the core layer; and a dielectric layer that covers a top surface of the conductive layer and a lateral surface of the conductive layer, wherein a lowermost surface of the dielectric layer is coplanar with the bottom surface of the core layer, and wherein a height of the dummy layer is in a range of about 1 μm to about 10 μm.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates a cross-sectional view showing a semiconductor package according to one or more embodiments of the disclosure;

FIG. 2 illustrates an enlarged view showing section A of FIG. 1;

FIGS. 3, 4, 5, 6 and 7 illustrate plan views showing an interposer according to one or more embodiments of the disclosure; and

FIGS. 8, 9, 10, 11, 12, 13 and 14 illustrate cross-sectional views showing a method of fabricating an interposer according to one or more embodiments of the disclosure.

### DETAILED DESCRIPTION

The following will now describe a semiconductor package according to the disclosure with reference to the accompanying drawings.

In the following description, like reference numerals refer to like elements throughout the specification. As used herein, a plurality of “unit”, “module”, “member”, and “block” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms first, second, third, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

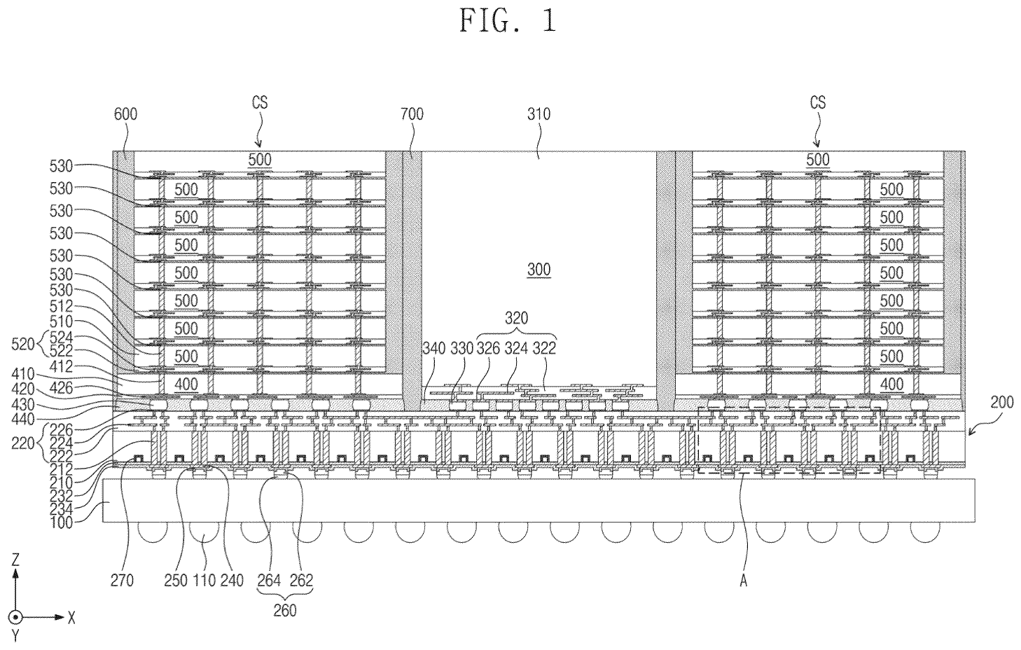

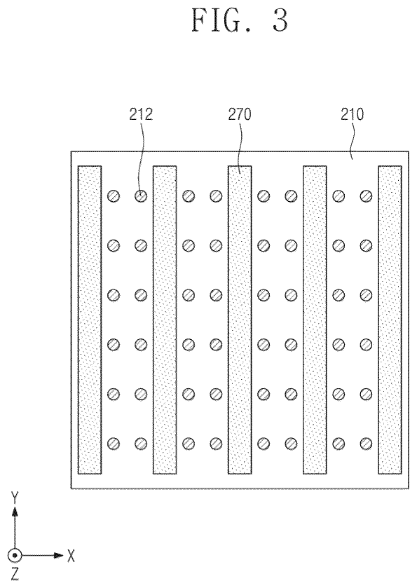

FIG. 1 illustrates a cross-sectional view showing a semiconductor package according to one or more embodiments of the disclosure. FIG. 1 illustrates an enlarged view of section A depicted in FIG. 1, showing an interposer according to one or more embodiments of the disclosure. FIGS. 3 to 7 illustrate plan views showing a top surface of a core layer in an interposer according to one or more embodiments of the disclosure.

As used herein, a first direction X and a second direction Y are defined to refer to directions that are parallel to a top surface of the package substrate 100 and orthogonal to each other, and a third direction Z is defined to refer to a direction perpendicular to the top surface of the package substrate 100.

Referring to FIGS. 1, 2, and 3, the package substrate 100 may be provided. The package substrate 100 may be a printed circuit board (PCB). For example, the package substrate 100 may have a central portion and also have peripheral portions for wiring connection above and below the central portion. The package substrate 100 may be provided with external pads to which external terminals 110 are coupled, as is discussed in more detail below.

The package substrate 100 may be provided with external terminals 110 on the bottom surface thereof. The external terminals 110 may include solder balls or solder bumps. Based on type and arrangement of the external terminals 110, a semiconductor package may be provided in the form of a ball grid array (BGA) type, a fine ball-grid array (FBGA) type, or a land grid array (LGA) type. The external terminals 110 may include a conductive metallic material. For example, the external terminals 110 may include at least one metal selected from tin (Sn), lead (Pb), silver (Ag), zinc (Zn), nickel (Ni), copper (Cu), and aluminum (Al).

An interposer 200 may be disposed on the package substrate 100. When viewed in plan, the interposer 200 may overlap the package substrate 100. The interposer 200 may include a core layer 210, first through vias 212, an upper wiring layer 220, and upper pads 226.

The core layer 210 may be provided. The core layer 210 may have a plate shape. The core layer 210 may include on core pattern when viewed in plan. The core layer 210 may include silicon (Si). For example, the core layer 210 may be a silicon substrate.

The upper wiring layer 220 may be disposed on a top surface of the core layer 210. The upper wiring layer 220 may cover the top surface of the core layer 210. The upper wiring layer 220 may include an upper dielectric pattern 222 and an upper wiring pattern 224.

The upper dielectric pattern 222 may include a dielectric polymer or a photo-imageable dielectric (PID). The photo-imageable dielectric may include, for example, at least one selected from photosensitive polyimide, polybenzoxazole, phenolic polymers, and benzocyclobutene polymers. Alternatively, the upper dielectric pattern 222 may include a dielectric material. For example, the upper dielectric pattern 222 may include silicon oxide (SiO), silicon nitride (SiN), or silicon oxynitride (SiON).

The upper wiring pattern 224 may be provided in the upper dielectric pattern 222. The upper wiring pattern 224 may horizontally or vertically extend in the upper dielectric pattern 222. In the upper dielectric pattern 222, the upper wiring pattern 224 may be electrically connected to another upper wiring pattern 224 adjacent thereto. A portion of the upper wiring pattern 224 may be exposed on a top surface of the upper dielectric pattern 222. The upper wiring pattern 224 may include a conductive material, such as copper (Cu).

The upper pads 226 may be provided on a top surface of the upper wiring layer 220. The upper pads 226 may be a portion of the upper wiring pattern 224 exposed from the upper dielectric pattern 222 of the upper wiring layer 220, or discrete pads disposed on the upper dielectric pattern 222 of the upper wiring layer 220 and connected to the upper wiring pattern 224. The upper pads 226 may include a conductive material. For example, the upper pads 226 may include at least one metal selected from copper (Cu), aluminum (Al), tungsten (W), and titanium (Ti).

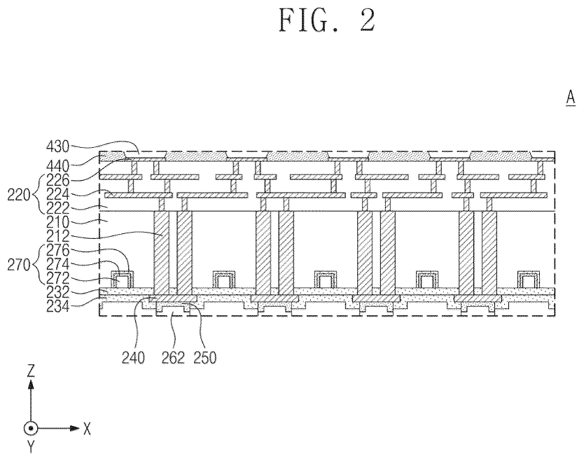

For convenience of description, FIGS. 1 and 2 depict that the upper wiring pattern 224 is provided in one upper dielectric pattern 222, but the disclosure is not limited thereto. According to one or more embodiments, the upper dielectric pattern 222 may include a plurality of dielectric layers that are stacked on each other. A single wiring layer may be constituted by one dielectric layer and a portion of the upper wiring pattern 224 provided in the one dielectric layer, and the upper wiring layer 220 may have a structure in which a plurality of wiring layers are stacked. The following description will be described with reference to FIGS. 1 and 2.

The first through via 212 may vertically penetrate the core layer 210. The first through via 212 may extend toward the top surface of the core layer 210 to come into electrical connection with the upper wiring pattern 224 of the upper wiring layer 220. The first through via 212 may extend toward and protrude from a bottom surface of the core layer 210. The first through via 212 may be provided in plural.

The first through vias 212 may be arranged along the first direction X and the second direction Y. For example, two neighboring first through vias 212 may be arranged along the second direction Y. The first through vias 212 arranged in one row in the second direction Y may be spaced apart in the first direction X from the first through vias 212 arranged in another row in the second direction Y. Alternatively, the first through vias 212 may be disposed in a grid shape. In one or more embodiments, the first through vias 212 may be arranged in rows, which rows may be shifted from each other in the first direction X or in the second direction Y. For example, the first through vias 212 may be disposed in a zigzag shape along the first direction X or the second direction Y. Alternatively, the first through vias 212 may be arranged in a honeycomb shape. The following description will be disclosed with reference continuously to FIGS. 1 and 2.

A dummy structure 270 may be provided on a lower portion of the core layer 210. For example, the dummy structure 270 may be provided in a recess formed on the bottom surface of the core layer 210. A bottom surface of the dummy structure 270 may be exposed on the bottom surface of the core layer 210. The bottom surface of the dummy structure 270 may be coplanar with the bottom surface of the core layer 210. The dummy structure 270 may be vertically spaced apart from the upper wiring layer 220. The dummy structure 270 may be horizontally spaced apart from the first through vias 212. The dummy structure 270 may be electrically insulated from the first through vias 212 and the upper wiring pattern 224 of the upper wiring layer 220. The dummy structure 270 will be discussed in detail below with reference to FIGS. 2 and 3.

The dummy structure 270 may include a dummy layer 272, a barrier layer 274, and a dielectric layer 276. The dummy layer 272 may be disposed on the lower portion of the core layer 210 to be exposed on the bottom surface of the core layer 210. In this case, the dummy layer 272 may have a height of about 1 μm to about 10 μm. In this description, the term “height” may refer to a distance in the third direction Z between two opposing surfaces. The dummy layer 272 may include tungsten (W), copper (Cu), or aluminum (Al).

The barrier layer 274 may be interposed between the core layer 210 and the dummy layer 272. The barrier layer 274 may cover a top surface and lateral surfaces of the dummy layer 272. In this case, a lowermost end of the barrier layer 274 may be located at the same vertical level as that of the bottom surface of the core layer 210. A bottom surface of the barrier layer 274 may be coplanar with the bottom surface of the core layer 210. The barrier layer 274 may prevent diffusion of metallic materials included in the dummy layer 272. The barrier layer 274 may be a conductive layer that surrounds the dummy layer 272. The barrier layer 274 may include titanium (Ti), titanium nitride (TiN), tantalum (Ta), or tantalum nitride (TaN).

According to one or more embodiments, a seed layer may be provided between the barrier layer 274 and the dummy layer 272 or between the barrier layer 274 and the core layer 210. The seed layer may surround an inner surface of the barrier layer 274 or an outer surface of the barrier layer 274. The seed layer may be a conductive layer. The seed layer may include the same material as that of the dummy layer 272. For example, the seed layer may include tungsten (W), copper (Cu), or aluminum (Al). For another example, the seed layer may include gold (Au) or silver (Ag). In an embodiment, the seed layer may be omitted. According to one or more embodiments, the barrier layer 274 may be used as the seed layer.

The dielectric layer 276 may be interposed between the barrier layer 274 and the core layer 210 to cover a top surface and lateral surfaces of the barrier layer 274. In this case, a lowermost end of the dielectric layer 276 may be located at the same vertical level as that of the bottom surface of the core layer 210. A bottom surface of the dielectric layer 276 may be coplanar with the bottom surface of the core layer 210. As the dielectric layer 276 is provided in the dummy structure 270, the dummy structure 270 may be electrically insulated from the first through vias 212 and the upper wiring pattern 224 of the upper wiring layer 220. The dielectric layer 276 may include silicon nitride (SiN), silicon oxide (SiO), silicon oxynitride (SiON), or tetraethylorthosilicate (TEOS).

The dummy structure 270 may be provided as discussed above. According to one or more embodiments of the disclosure, as the dummy structure 270 is inserted into a lower portion of the core layer 210, the interposer 200 may be prevented from warpage caused by heat and pressure that occur when a first semiconductor chip 300 and chip stacks CS are mounted as discussed below. It may therefore be possible to provide a semiconductor package including the interposer 200 with improved structural stability.

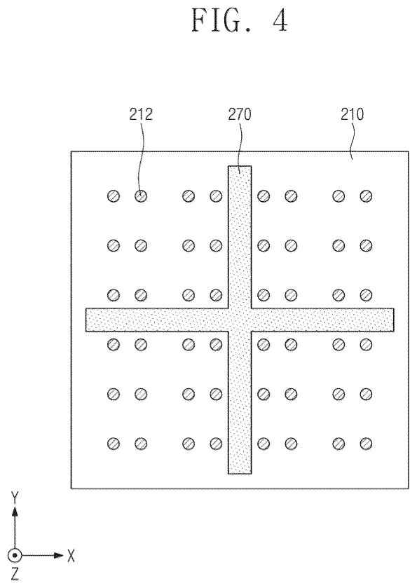

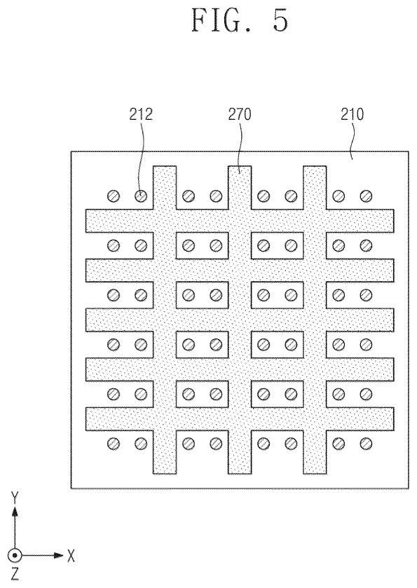

The dummy structure 270 may be provided in plural. The dummy structures 270 may be disposed on a dummy region. In this description, the dummy region may indicate a region other than a region where the first through vias 212 are disposed on the core layer 210. Each of the dummy structures 270 may have a linear shape or a bar shape. As shown in FIG. 3, the dummy structures 270 may extend in the second direction Y to reside between the first through vias 212 arranged in one row in the second direction Y and the first through vias 212 arranged in another row in the second direction Y. Alternatively, as shown in FIG. 4, each of the dummy structures 270 may extend in the first direction X or the second direction Y, and the dummy structures 270 may overlap each other. For example, the dummy structures 270 may cross each other. In this case, the overlap of the dummy structures 270 may be disposed on a central portion of the core layer 210. Alternatively, as shown in FIG. 5, the dummy structures 270 may have a grid shape.

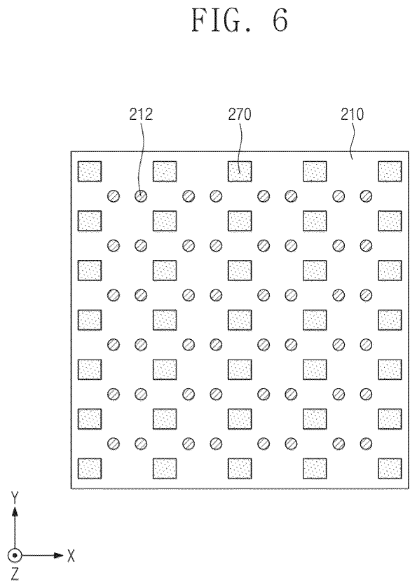

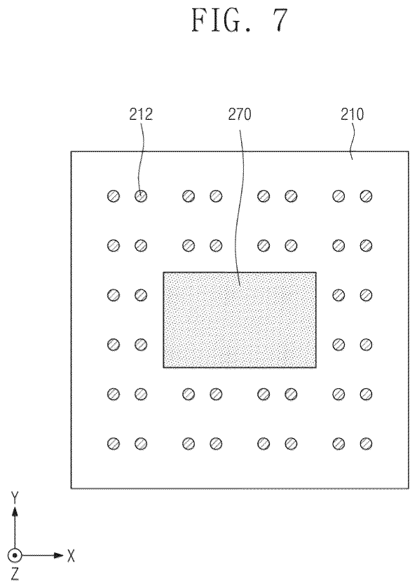

According to one or more embodiments, each of the dummy structures 270 may have a block shape. As shown in FIG. 6, on the bottom surface of the core layer 210, each of the block-shaped dummy structures 270 may be horizontally spaced apart from the first through vias 212. Alternatively, one block-shaped dummy structure 270 may be disposed on the bottom surface of the core layer 210. As shown in FIG. 7, the dummy structure 270 may be disposed on a central portion of the core layer 210. The following description will be disclosed with reference continuously to FIGS. 1 and 2.

A first passivation layer 232 may be provided on the bottom surface of the core layer 210. The first passivation layer 232 may cover the dummy structure 270 and the bottom surface of the core layer 210. The first passivation layer 232 may surround the first through vias 212 that protrude from the bottom surface of the core layer 210. For example, the first through vias 212 may penetrate the first passivation layer 232. A bottom surface of the first passivation layer 232 may be coplanar with bottom surfaces of the first through vias 212. The first passivation layer 232 may include a dielectric material. The first passivation layer 232 may include silicon nitride (SiN), silicon oxide (SiO), silicon oxynitride (SiON), or tetraethylorthosilicate (TEOS).

The first passivation layer 232 may be provided with lower pads 240 on the bottom surface thereof. The lower pads 240 may be electrically connected to the first through vias 212. For example, portions of top surfaces of the lower pads 240 may be in contact with the bottom surfaces of the first through vias 212 that protrude onto the bottom surface of the first passivation layer 232. The lower pads 240 may include a conductive material. For example, the lower pads 240 may include at least one metal selected from copper (Cu), aluminum (Al), tungsten (W), and titanium (Ti).

A second passivation layer 234 may be provided on the bottom surface of the first passivation layer 232. The second passivation layer 234 may cover the bottom surface of the first passivation layer 232 and a lateral surface of each of the lower pads 240, and a portion of a bottom surface of each of the lower pads 240. For example, the second passivation layer 234 may expose a remaining portion of the bottom surface of each of the lower pads 240. The second passivation layer 234 may include a dielectric material. The second passivation layer 234 may include silicon nitride (SiN), silicon oxide (SiO), silicon oxynitride (SiON), or tetraethylorthosilicate (TEOS).

A first semiconductor chip 300 may be provided on the interposer 200. The first semiconductor chip 300 may include a first semiconductor substrate 310 and a first circuit layer 320.

The first semiconductor substrate 310 may include a semiconductor substrate. For example, the first semiconductor substrate 310 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG). The first semiconductor substrate 310 may include, for example, silicon (Si), germanium (Ge), silicon germanium (SiGe), gallium arsenic (GaAs), indium gallium arsenic (InGaAs), aluminum gallium arsenic (AlGaAs), or a mixture thereof. An integrated circuit may be provided on a bottom surface of the first semiconductor substrate 310. The integrated circuit may include a logic circuit or a memory circuit. For example, the first semiconductor chip 300 may be a logic chip or a memory chip. The disclosure, however, is not limited thereto, and the first semiconductor chip 300 may include a logic chip, a memory chip, a passive element, or a semiconductor chip including various integrated elements. The bottom surface of the first semiconductor chip 300 may be an active surface, and a top surface of the first semiconductor chip 300 may be an inactive surface. For example, the first semiconductor chip 300 may be disposed in a face-down state on the interposer 200.

The first circuit layer 320 may be disposed on the bottom surface of the first semiconductor substrate 310. For example, the first circuit layer 320 may include a first chip dielectric pattern 322 and a first chip wiring pattern 324 that are formed on the bottom surface of the first semiconductor substrate 310. The first circuit layer 320 may further include a circuit pattern or a protection layer, if necessary.

The first chip dielectric pattern 322 may cover the integrated circuit on the bottom surface of the first semiconductor substrate 310. The first chip dielectric pattern 322 may include a dielectric material. For example, the first chip dielectric pattern 322 may include silicon oxide (SiO), silicon nitride (SiN), silicon oxynitride (SiON), silicon carbonitride (SiCN), or a dielectric polymer. Alternatively, the first chip dielectric pattern 322 may include a dielectric polymer or a photo-imageable dielectric (PID). The photo-imageable dielectric may include, for example, at least one selected from photosensitive polyimide, polybenzoxazole, phenolic polymers, and benzocyclobutene polymers.

The first chip wiring pattern 324 may be provided in the first chip dielectric pattern 322. The first chip wiring pattern 324 may be electrically connected to the integrated circuit formed on the bottom surface of the first semiconductor substrate 310. The first chip wiring pattern 324 may include a conductive material. For example, the first chip wiring pattern 324 may include copper (Cu) or aluminum (Al).

The first semiconductor chip 300 may include first chip pads 326 provided on a bottom surface of the first semiconductor chip 300. The first chip pads 326 may be disposed on the bottom surface of the first semiconductor chip 300 or a bottom surface of the first circuit layer 320. The first chip pads 326 may be exposed on the bottom surface of the first semiconductor chip 300. The first chip pads 326 may be electrically connected through the first chip wiring pattern 324 in the first circuit layer 320 to the integrated circuit formed on the bottom surface of the first semiconductor substrate 310.

The first semiconductor chip 300 may be mounted on the interposer 200. For example, the first semiconductor chip 300 may be flip-chip mounted on the interposer 200. The first semiconductor chip 300 may be electrically connected thorough second connection terminals 330 to the upper pads 226 of the interposer 200. The second connection terminals 330 may be provided between the first chip pads 326 and the upper pads 226 of the interposer 200. The first semiconductor chip 300 may be electrically connected through the second connection terminals 330 and the interposer 200 to the chip stacks CS which will be discussed below. As the first semiconductor chip 300 is mounted through the second connection terminals 330, the first semiconductor chip 300 may be spaced apart from a top surface of the interposer 200.

A first underfill layer 340 may be provided between the top surface of the interposer 200 and the bottom surface of the first semiconductor chip 300. The first underfill layer 340 may fill a space between the interposer 200 and the first semiconductor chip 300. The first underfill layer 340 may surround the upper pads 226, the first chip pads 326, and the second connection terminals 330. The first underfill layer 340 may include a dielectric material. For example, the first underfill layer 340 may include a non-conductive film (NCF) or a non-conductive paste (NCP). The first underfill layer 340 may include a dielectric polymer. For example, the first underfill layer 340 may be formed of an epoxy-based material devoid of conductive particles.

The chip stacks CS may be provided on the interposer 200. On the interposer 200, the chip stacks CS may be disposed horizontally spaced apart from the first semiconductor chip 300. The following will focus on a single chip stack CS. The chip stack CS may include a base chip 400, second semiconductor chips 500 stacked on the base chip 400, and a first molding layer 600 that surrounds the second semiconductor chips 500.

The base chip 400 may include a base substrate 410. The base substrate 410 may be a semiconductor substrate. For example, the base substrate 410 may be a wafer-level semiconductor substrate formed of a semiconductor material, such as silicon (Si). The base chip 400 may have a bottom surface as an active surface. For example, an integrated element or integrated circuits may be formed on a bottom surface of the base substrate 410.

The base chip 400 may include a base circuit layer 420 and second through vias 412. The base circuit layer 420 may be provided on the bottom surface of the base substrate 410. The base circuit layer 420 may include the integrated element and the integrated circuits. For example, the base circuit layer 420 may be a memory circuit. For example, the base chip 400 may be a memory chip, such as a dynamic random-access memory (DRAM), a static random-access memory (SRAM), a magnetic random-access memory (MRAM), or a Flash memory. Alternatively, the base circuit layer 420 may be a logic circuit. In this case, the base chip 400 may be a logic chip. The second through vias 412 may penetrate the base chip 400 in a direction perpendicular to the top surface of the interposer 200. The second through vias 412 may be electrically connected to the base circuit layer 420.

The base circuit layer 420 may be provided with second chip pads 426 on a bottom surface thereof. The second chip pads 426 may be a portion of a circuit pattern in the base circuit layer 420 or discrete pads connected to the circuit pattern. The second chip pads 426 may include a conductive material. For example, the second chip pads 426 may include at least one metal selected from copper (Cu), aluminum (Al), tungsten (W), and titanium (Ti).

The second semiconductor chip 500 may be provided on the base chip 400. The second semiconductor chip 500 may have a width less than that of the base chip 400. The width of the second semiconductor chip 500 and the width of the base chip 400 may each be a width measured in a direction parallel to the top surface of the interposer 200. The second semiconductor chip 500 may include a second semiconductor substrate 510, a second circuit layer 520, and a third through via 512.

The second semiconductor substrate 510 may be a semiconductor substrate. For example, the second semiconductor substrate 510 may include silicon (Si). The second circuit layer 520 disposed on a bottom surface of the second semiconductor substrate 510 may include a memory circuit comprising second semiconductor dielectric pattern 522 and second semiconductor wiring pattern 524. For example, the second semiconductor chip 500 may be a memory chip, such as a dynamic random-access memory (DRAM), a static random-access memory (SRAM), a magnetic random-access memory (MRAM), or a Flash memory. The third through via 512 may penetrate the second semiconductor chip 500 in a direction perpendicular to the top surface of the interposer 200. The third through via 512 and the second circuit layer 520 may be electrically connected to each other. The second semiconductor chip 500 may have a bottom surface as an active surface. The second semiconductor chip 500 may be provided with connection bumps 530 on a bottom surface thereof. The connection bumps 530 may reside between and electrically connect the base chip 400 and the second semiconductor chip 500.

The second semiconductor chip 500 may be provided in plural. For example, a plurality of second semiconductor chips 500 may be stacked on the base chip 400. The number of stacked second semiconductor chips 500 may be about 8 to 32. The connection bumps 530 may be correspondingly provided between the second semiconductor chips 500. An uppermost second semiconductor chip 500 may not include the third through via 512. In addition, the uppermost second semiconductor chip 500 may have a thickness greater than those of other second semiconductor chips 500 disposed thereunder.

An adhesion layer may be provided between the second semiconductor chips 500. The adhesion layer may include a non-conductive film (NCF). The adhesion layer may surround the connection bumps 530, while filling a space between the second semiconductor chips 500. The adhesion layer may prevent the occurrence of an electrical short between the connection bumps 530.

The first molding layer 600 may be disposed on a top surface of the base chip 400. The first molding layer 600 may cover the base chip 400. The first molding layer 600 may surround the second semiconductor chips 500. A top surface of the first molding layer 600 may be coplanar with a top surface of the uppermost second semiconductor chip 500. The uppermost second semiconductor chip 500 may be exposed on the top surface of the first molding layer 600. The first molding layer 600 may include a dielectric polymer material. For example, the first molding layer 600 may include an epoxy molding compound (EMC).

The chip stack CS may be provided as discussed above. The chip stack CS may be mounted on the interposer 200. For example, the chip stacks CS may be coupled to the upper pads 226 through third connection terminals 430 of the base chip 400. The third connection terminals 430 may be in contact with top surfaces of the upper pads 226 and the bottom surface of the base circuit layer 420. A second underfill layer 440 may surround the upper pads 226, the second chip pads 426, and the third connection terminals 430, while filling a space between the chip stack CS and the interposer 200.

A second molding layer 700 may be disposed on the top surface of the interposer 200. The second molding layer 700 may surround the first semiconductor chip 300, the first underfill layer 340, the chip stacks CS, and the second underfill layers 440. The second molding layer 700 may have a top surface coplanar with a top surface of the first semiconductor chip 300 and the top surface of the uppermost second semiconductor chip 500 in each of the chip stacks CS, and the first semiconductor chip 300 and the uppermost second semiconductor chip 500 may be exposed on the top surface of the second molding layer 700. Alternatively, the second molding layer 700 may cover the first semiconductor chip 300 and the chip stacks CS. The second molding layer 700 may include a dielectric polymer material. For example, the second molding layer 700 may include an epoxy molding compound (EMC).

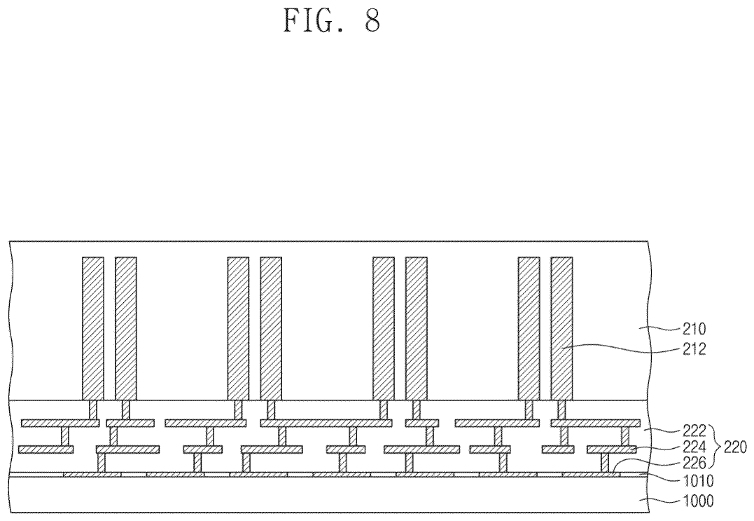

FIGS. 8 to 14 illustrate cross-sectional views showing a method of fabricating the interposer 200 according to one or more embodiments of the disclosure.

Referring to FIG. 8, a carrier substrate 1000 may be provided. The carrier substrate 1000 may be a dielectric substrate including glass or polymer, or may be a conductive substrate including metal. An adhesive member may be provided on a top surface of the carrier substrate 1000. For example, the adhesive member may include a glue tape.

A core layer 210 may be provided on the carrier substrate 1000. The core layer 210 may be provided in the form of a semiconductor wafer. First through vias 212 may be formed to vertically penetrate the core layer 210. For example, through holes may be formed to penetrate the core layer 210, and then the through holes may be filled with a conductive material to form the first through vias 212. The through holes may extend from a bottom surface of the core layer 210 toward a top surface of the core layer 210, but may not completely penetrate the core layer 210. Therefore, the first through vias 212 may not be exposed on the top surface of the core layer 210. A dielectric material may be deposited on the bottom surface of the core layer 210, and then the dielectric material may be patterned to form an upper dielectric pattern 222. A conductive material may be deposited on the upper dielectric pattern 222, and then the conductive material may be patterned to form an upper wiring pattern 224. The formation of the upper dielectric pattern 222 and the upper wiring pattern 224 may be performed to form an upper wiring layer 220. A dielectric material 1010 may be deposited and patterned on the upper wiring layer 220 to form openings that expose the upper wiring pattern 224, and then the openings may be filled with a conductive material to form upper pads 226.

The core layer 210 on which the upper wiring layer 220 is formed may be attached to the carrier substrate 1000. For example, the core layer 210 may be disposed on the carrier substrate 1000 to allow the bottom surface of the core layer 210 to face toward the carrier substrate 1000. In such a case, the upper pads 226 of the upper wiring layer 220 may be attached to the top surface of the carrier substrate 1000.

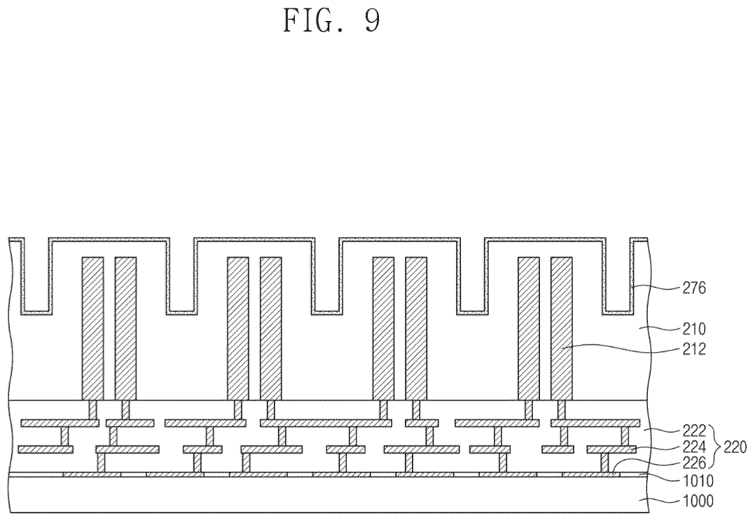

Referring to FIG. 9, a portion of the core layer 210 may be removed. For example, a photo-imageable dielectric may be deposited and patterned on the top surface of the core layer 210, and then the photo-imageable dielectric may be used as an etching mask to perform an etching process to form trenches. The first through vias 212 may not be exposed. For example, the trenches may be horizontally spaced apart from the first through vias 212. Afterwards, the photo-imageable dielectric may be removed. Alternatively, when a portion of the core layer 210 is removed by a chemical mechanical polishing (CMP) process or a grinding process which will be discussed below, the photo-imageable dielectric may also be removed.

A deposition process may be performed on the top surface of the core layer 210 and the trenches, thereby forming a dielectric layer 276. For example, the deposition process may be a chemical vapor deposition (CVD) process. The dielectric layer 276 may conformally cover the top surface of the core layer 210 and the trenches.

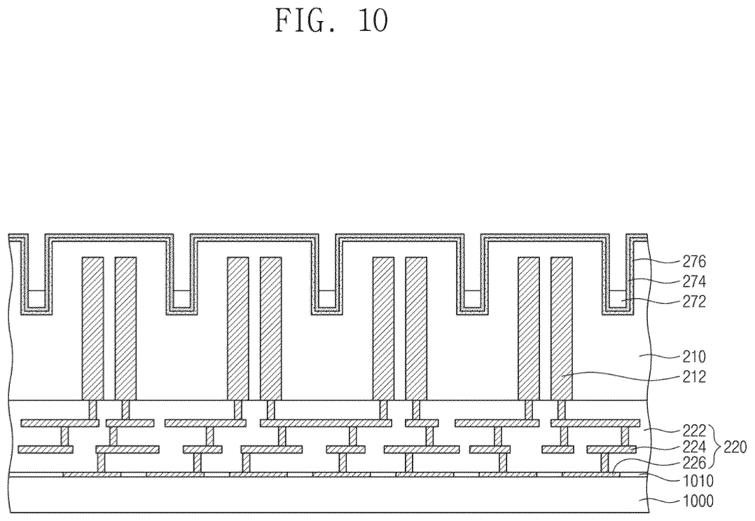

Referring to FIG. 10, a barrier layer 274 may be formed on a resultant structure of FIG. 9. The dielectric layer 276 may undergo a deposition process to form the barrier layer 274. For example, the deposition process may be a physical vapor deposition (PVD) process. The barrier layer 274 may conformally cover the dielectric layer 276.

A seed layer may be formed on the barrier layer 274. The barrier layer 274 may undergo a deposition process to form the seed layer. For example, the deposition process may be a physical vapor deposition (PVD) process. The seed layer may conformally cover the barrier layer 274. Afterwards, the seed layer may be used as a seed to perform an electroplating process to form a dummy layer 272 on the barrier layer 274. When the seed layer is formed of the same material as that of the dummy layer 272, an invisible boundary may be provided between the seed layer and the dummy layer 272. For example, the seed layer may be formed as a portion of the dummy layer 272. Alternatively, when the seed layer is formed of a different material from that of the dummy layer 272, a visible boundary may be provided between the seed layer and the dummy layer 272.

The dummy layer 272 may undergo an etching process to form a plurality of separated dummy layers 272 in the trenches. In this operation, the etching process may be performed until a top surface of each of the dummy layers 272 is located at a lower level than that of a top surface of each of the first through vias 212.

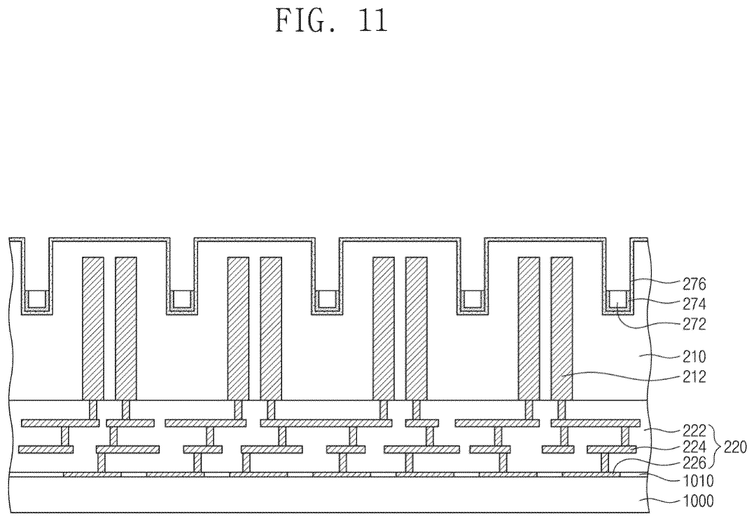

Referring to FIG. 11, a resultant structure of FIG. 10 may undergo an etching process to remove a portion of the barrier layer 274. For example, the etching process may be executed to remove barrier layer 274 on the top surface of the core layer 210 and a portion of the barrier layer 274 in the openings. Therefore, one continuous barrier layer 274 may be separated into a plurality of barrier layers 274 that correspondingly surround the dummy layers 272. In this operation, a portion of the barrier layer 274 may be removed to allow top surfaces of the barrier layers 274 to become coplanar with corresponding top surfaces of the dummy layers 272.

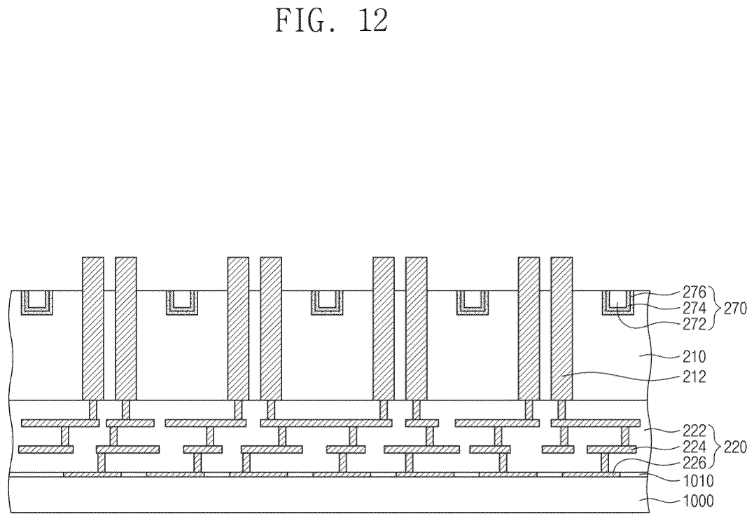

Referring to FIG. 12, a resultant structure of FIG. 11 may undergo an etching process to remove a portion of the dielectric layer 276. For example, the etching process may be performed to remove the dielectric layer on the top surface of the core layer 210 and a portion of the dielectric layer 276 in the openings. Therefore, one continuous dielectric layer 276 may be separated into a plurality of dielectric layers 276 that correspondingly surround the barrier layers 274. In this operation, a portion of the dielectric layer 276 may be removed to allow the top surfaces of the dielectric layers 276 to become coplanar with corresponding top surfaces of the barrier layers 274.

The core layer 210 may then undergo a chemical mechanical polishing (CMP) process or a grinding process to remove a portion of the core layer 210. The chemical mechanical polishing process or the grinding process may continue until the top surface of the core layer 210 becomes coplanar with the top surface of the dielectric layer 276. The first through vias 212 may not be removed by the chemical mechanical polishing process or the grinding process. For example, the first through vias 212 may protrude onto the top surface of the core layer 210.

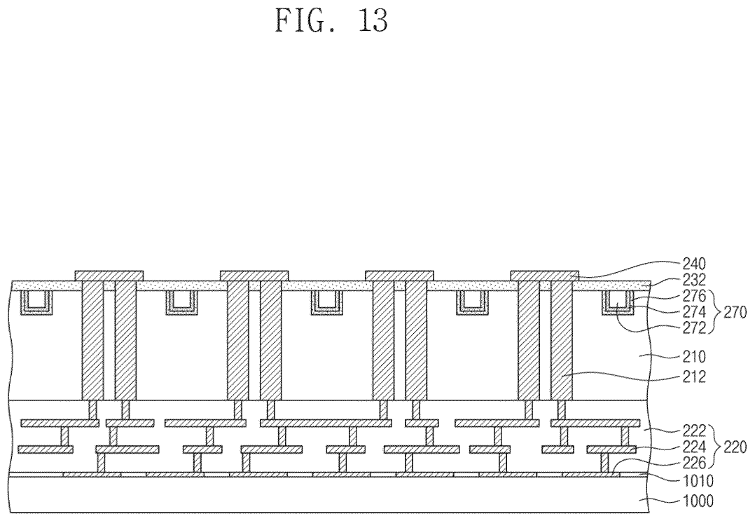

Referring to FIG. 13, a first passivation layer 232 may be formed to cover the top surface of the core layer 210 and the first through vias 212 that protrude onto the top surface of the core layer 210. For example, the core layer 210 may undergo a chemical vapor deposition (CVD) process to form the first passivation layer 232. The first passivation layer 232 may conformally cover the top surface of the core layer 210 and the first through vias 212 that protrude onto the top surface of the core layer 210.

A chemical mechanical polishing (CMP) process may then be performed on the first passivation layer 232. The chemical mechanical polishing process may partially remove an upper portion of the first passivation layer 232. The chemical mechanical polishing process may continue until the top surfaces of the first through vias 212 are exposed. Even after the top surfaces of the first through vias 212 are exposed, the chemical mechanical polishing process may be continuously performed if necessary. As a result, upper portions of the first through vias 212 may be partially removed. A top surface of the first passivation layer 232 may be coplanar with the top surface of each of the first through vias 212 as a result of the chemical mechanical polishing process.

Lower pads 240 may be formed on the first passivation layer 232. For example, a dielectric material may be deposited on the first passivation layer 232, and the dielectric material may be patterned to form openings that expose the first through vias 212. The openings may be filled with a conductive material to form the lower pads 240. Then, the dielectric material may be removed.

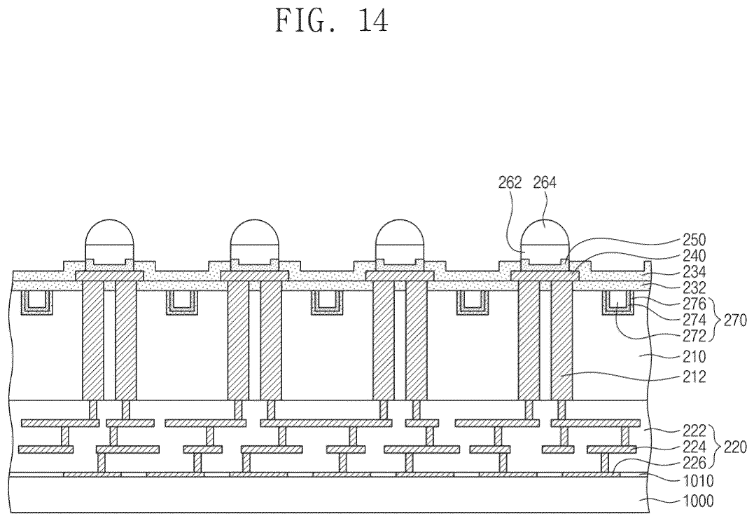

Referring to FIG. 14, a second passivation layer 234 may be formed on a resultant structure of FIG. 13. For example, the first passivation layer 232 may undergo a chemical vapor deposition (CVD) process to form the second passivation layer 234. The second passivation layer 234 may conformally cover the lower pads 240 and the top surface of the first passivation layer 232.

A dielectric material may then be deposited on the second passivation layer 234, and the dielectric material may be patterned to form recesses that expose the lower pads 240. A typical process may be performed on the recesses to form under-bump patterns 250 and first connection terminals 260 on the under-bump patterns 250. For example, a conductive layer may be formed on the second passivation layer 234, and then the conductive layer may be patterned to form the under-bump patterns 250. The under-bump patterns 250 may be portions of the conductive layer positioned in the recesses. A sacrificial layer may then be formed on the second passivation layer 234, recesses may be formed to expose the under-bump patterns 250, and the recesses may be filled with a conductive material to form filler parts 262 of first connection terminals 260. A solder material may be attached to the filler parts 262 of the first connection terminals 260 to form cap parts 264 of the first connection terminals 260. Afterwards, the sacrificial layer may be removed.

Thereafter, the carrier substrate 1000 may be removed to fabricate an interposer 200 discussed with reference to FIGS. 1 and 2. According to one or more embodiments of the disclosure, as the dummy structure 270 is inserted into a lower portion of the core layer 210, the interposer 200 may be prevented from warpage caused by heat and pressure that occur when semiconductor chips are mounted on the interposer 200. It may therefore be possible to provide a semiconductor package including the interposer 200 with improved structural stability.

In a semiconductor package according to one or more embodiments of the disclosure, a dummy structure may be inserted into a lower portion of an interposer. Therefore, the interposer may be prevented from warpage caused by heat and pressure that occur when semiconductor chips are mounted on the interposer. Accordingly, a semiconductor package may be provided which includes the interposer with improved structural stability.

Although the disclosure has been described in connection with one or more embodiments illustrated in the accompanying drawings, it will be understood by one of ordinary skill in the art that variations in form and detail may be made therein without departing from the spirit of the disclosure. The above disclosed embodiments should thus be considered illustrative and not restrictive.

What is claimed is:

1. An interposer comprising:
a core layer;
an upper wiring layer on the core layer;
a lower pad on a bottom surface of the core layer;
a through via that vertically penetrates the core layer and connects the upper wiring layer to the lower pad; and
a dummy structure on a lower portion of the core layer,
wherein the dummy structure comprises:
a dummy layer comprising a bottom surface that is coplanar with the bottom surface of the core layer;
a barrier layer between the core layer and the dummy layer; and
a dielectric layer between the core layer and the barrier layer, and
wherein the dummy structure is horizontally spaced apart from the through via and is electrically insulated from the through via.

2. The interposer of claim 1,
wherein the barrier layer covers a top surface of the dummy layer and a lateral surface of the dummy layer,
wherein the dielectric layer covers a top surface of the barrier layer and a lateral surface of the barrier layer, and
wherein a lowermost end of the barrier layer, a lowermost end of the dielectric layer, and the bottom surface of the core layer are at a same vertical level.

3. The interposer of claim 1, further comprising a first passivation layer between the core layer and the lower pad,
wherein the first passivation layer covers the dummy structure and the bottom surface of the core layer.

4. The interposer of claim 3,
wherein the through via penetrates the first passivation layer and is coupled to the lower pad, and
wherein a bottom surface of the first passivation layer is coplanar with a bottom surface of the through via.

5. The interposer of claim 3, further comprising a second passivation layer on a bottom surface of the first passivation layer,
wherein the second passivation layer covers the bottom surface of the first passivation layer, and
wherein the second passivation layer covers at least a portion of a bottom surface of the lower pad and exposes a remaining portion of the bottom surface of the lower pad.

6. The interposer of claim 5, wherein each of the first passivation layer and the second passivation layer comprises silicon oxide (SiO), silicon nitride (SiN), or silicon oxynitride (SiON).

7. The interposer of claim 1, wherein the dummy structure is vertically spaced apart from the upper wiring layer and is electrically insulated from the upper wiring layer.

8. The interposer of claim 1, wherein a height of the dummy layer is in a range of about 1 μm to about 10 μm.

9. The interposer of claim 1, wherein the dummy structure comprises a linear shape, a bar shape, a grid shape, or a block shape.

10. The interposer of claim 1, wherein the dummy layer comprises tungsten (W), copper (Cu), or aluminum (Al).

11. The interposer of claim 1, wherein the barrier layer comprises titanium (Ti), titanium nitride (TiN), tantalum (Ta), or tantalum nitride (TaN).

12. A semiconductor package comprising:
a package substrate;
an interposer on the package substrate;
a semiconductor chip on the interposer; and
a chip stack on the interposer and horizontally spaced apart from the semiconductor chip,
wherein the interposer comprises:
a core layer;
an upper wiring layer on the core layer;
a dummy structure in the core layer and exposed on a bottom surface of the core layer;
a passivation layer that covers the dummy structure and the bottom surface of the core layer;
a through via that vertically penetrates the core layer and the passivation layer and is connected to the upper wiring layer; and
a lower pad on the bottom surface of the core layer, wherein the lower pad is connected to the through via,
wherein the dummy structure is vertically spaced apart from the upper wiring layer, and
wherein the dummy structure is electrically insulated from the upper wiring layer.

13. The semiconductor package of claim 12, wherein the dummy structure is horizontally spaced apart from the through via and is electrically insulated from the through via.

14. The semiconductor package of claim 12,
wherein the interposer further comprises a barrier layer between the core layer and the dummy structure, and
wherein a lowermost surface of the barrier layer is exposed on the bottom surface of the core layer.

15. The semiconductor package of claim 14,
wherein the interposer further comprises a dielectric layer between the core layer and the barrier layer, and
wherein a lowermost surface of the dielectric layer is exposed on the bottom surface of the core layer.

16. The semiconductor package of claim 12, wherein a height of the dummy structure is in a range of about 1 μm to about 10 μm.

17. An interposer comprising:
a core layer;
an upper wiring layer on a top surface of the core layer, the upper wiring layer comprising an upper dielectric pattern and an upper wiring pattern in the upper dielectric pattern;
a dummy structure on a lower portion of the core layer, the dummy structure comprising a bar shape;
a first passivation layer that covers the dummy structure and a bottom surface of the core layer;
a through via that vertically penetrates the core layer and connects to the upper wiring layer, wherein a bottom surface of the through via is coplanar with a bottom surface of the first passivation layer;
a lower pad on the bottom surface of the first passivation layer and connected to the through via;
a second passivation layer that covers the bottom surface of the first passivation layer and comprises a recess exposing a portion of a bottom surface of the lower pad; and
an under-bump pattern on the recess,
wherein the dummy structure comprises:
a dummy layer comprising a bottom surface that is coplanar with the bottom surface of the core layer;
a conductive layer that covers a top surface of the dummy layer and a lateral surface of the dummy layer, wherein a lowermost surface of the conductive layer is coplanar with the bottom surface of the core layer; and
a dielectric layer that covers a top surface of the conductive layer and a lateral surface of the conductive layer,
wherein a lowermost surface of the dielectric layer is coplanar with the bottom surface of the core layer, and
wherein a height of the dummy layer is in a range of about 1 μm to about 10 μm.

18. The interposer of claim 17, wherein the dummy structure is horizontally spaced apart from the through via and is electrically insulated from the through via.

19. The interposer of claim 17, wherein the dummy structure is horizontally spaced apart from the upper wiring layer and is electrically insulated from the upper wiring pattern.

20. The interposer of claim 17, wherein the dummy layer comprises tungsten (W), copper (Cu), or aluminum (Al).
